(19) United States
(12) Patent Application Publication
(10) Pub. No.: US 2024/0203519 A1
(43) Pub. Date: Jun. 20, 2024

(54) TIME DEPENDENT DIELECTRIC BREAKDOWN RELIABILITY TESTING OF A SRAM

(71) Applicant: INTERNATIONAL BUSINESS MACHINES CORPORATION, ARMONK, NY (US)

(72) Inventors: Giuseppe La Rosa, Fishkill, NY (US); Bharat Biyani, Wappingers Falls, NY (US); Barry Paul Linder, Hastings-on-Hudson, NY (US)

(21) Appl. No.: 18/069,205

(22) Filed: Dec. 20, 2022

(51) Int. Cl. G11C 29/50; G01R 31/14; H10B 10/00

(52) U.S. Cl. CPC G11C 29/50004; G01R 31/14; G11C 29/50012; H10B 10/12; G11C 2029/5006

(57) ABSTRACT

A semiconductor device configured for individual reliability testing of a bit cell in a static random-access memory (SRAM). An SRAM includes a plurality of transistors. A first inverter and a second inverter cross-coupled to the first inverter are constructed of the plurality of transistors. A first access transistor and a second access transistor of the plurality of transistors are configured to share a word line bias. The second inverter and the second access transistor have a shared first gate connection and form respective bit cell devices each with two contacts. At least one contact of each of the respective bit cell devices is a floating diffusion contact, and a second contact of each of the respective bit cells is configured to be individually biased for reliability testing.

### BACKGROUND

### Technical Field

The present disclosure generally relates to structures and methods to evaluate a time dependent dielectric breakdown (TDDB) in a semiconductor device, and more particularly, to the (TDDB) of a bit cell in a static random access memory (SRAM) device.

### Description of the Related Art

SRAM devices may be grouped into SRAM bit cells that typically include up to six transistors in configurations to store bits. For example, an SRAM bit cell may include a bi-stable flip-flop that may be connected to an internal circuitry by access transistors. In the event that a cell is not addressed, the access transistors are closed and the data is latched within the flip-flop and kept in a stable state.

### SUMMARY

According to one embodiment, a semiconductor device is configured for individual reliability testing of a bit cell device in a static random-access memory (SRAM). An SRAM includes a plurality of transistors. A first inverter and a second inverter cross-coupled to the first inverter are constructed of the plurality of transistors. A first access transistor and a second access transistor of the plurality of transistors are configured to share a wordline bias. The second inverter and the second access transistor have a shared first gate connection and form respective bit cell devices each with two contacts. At least one contact of each of the respective bit cell devices is a floating diffusion contact, and a second contact of each of the respective bit cell devices is configured to be individually biased for reliability testing.

In one embodiment, the first inverter includes a first transistor and a second transistor of the plurality of transistors. The second inverter includes a third transistor and a fourth transistor of the plurality of transistors. The first access transistor and the second access transistor, respectively, include a fifth transistor and a sixth transistor of the SRAM device. The third transistor, fourth transistor, and fifth transistor have the shared first gate connection.

In one embodiment, the first transistor and second transistor have a shared second gate connection.

In one embodiment, the shared first gate includes a gate of the fifth transistor, a gate of the third transistor and a gate the fourth transistor, wherein the gate of the fifth transistor is connected via an inline gate-to-gate metal connection.

In one embodiment, the first transistor, the second transistor and the sixth transistor are electrically isolated from the third transistor, fourth transistor, and fifth transistor.

In one embodiment, the static random-access memory (SRAM) includes a modified design 6 transistor SRAM (SRAM_6T_RE) without diffusion-contact-to-inverter gate-short connections. There is an gate-to-gate metal connection between a gate of the fifth transistor and a gate of the third transistor and the fourth transistor to form the shared first gate.

In one embodiment, the SRAM_6T_RE is further configured for Time Dependent Dielectric Breakdown of the respective individual bit cell devices by including floating diffusion contacts to isolate the first transistor, the second transistor, and the sixth transistor.

In one embodiment, there is a plurality of static ram memory devices and at least one SRAM_6T_RE configured for TDDB reliability testing.

In one embodiment, the SRAM_6T-RE is configured to retain each of the bit cell devices including a pull-up (PU), pull-down (PD), and pass gate (PG) devices while conforming to Front End of Line (FEOL) of an adopted library cell design methodologies of an SRAM-6T.

In one embodiment, a given number of single bit cells devices of the modified 6T_SRAM_RE are wired in parallel to yield an assigned total area for a given bit cell device type.

According to one embodiment, a method of biasing a static random-access memory (SRAM) bit cell device of an SRAM memory modified for individual bit cell Time Dependent Dielectric Breakdown (TDDB) stress reliability testing, the method includes biasing an individual SRAM bit cell device for stressing via TDDB reliability testing Multiple combinations of stress voltages having different values higher than a predetermined maximum use voltage are applied to a given SRAM bit cell device to be stressed. A leakage current of the individual SRAM bit cell device undergoing TDDB reliability testing is recorded as well as a time period of the recording. The individual SRAM bit cell device to be stressed is selected from the group including a pull up, a pull down, a pass gate, or a combination of a pass gate and a pull down.

In one embodiment, the SRAM device is configured to include a gate-to-gate-metal connection and floating diffusion contacts on at least one contact of each bit cell. The multiple combinations of stress voltages having different values higher than a predetermined maximum use voltage are applied to a given SRAM bit cell device in increasing increments and performing a recording of the leakage current that occurred over a predetermined time period of the TDDB reliability testing.

According to one embodiment, a method of forming a semiconductor for individual reliability testing of a static random-access memory (SRAM) bit cell includes providing a static random-access memory (SRAM) including a plurality of transistors. A first inverter and a second inverter are formed from at least some of the plurality of transistors, the second inverter is cross-coupled to the first inverter. A first access transistor and a second access transistor of the plurality of transistors are configured to share a word line bias. The second inverter is connected to the second access transistor to have a shared first gate connection and form respective bit cell devices, each with two contacts. At least one contact of each of the respective bit cell devices is a floating diffusion contact. A second contact of each of the respective bit cell devices is individually biased for reliability testing.

In one embodiment, the bit cell devices are electrically isolated from the first transistor, the second transistor and the sixth transistor.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A is an illustration of a conventional 6T SRAM thin cell layout, and FIG. 1B is a schematic of the thin cell layout of FIG. 1A.

FIG. 2 is a schematic of a conventional SRAM cell design schematic showing that three different bit cell devices are exposed to Time Dependent Dielectric Breakdown aging at the same time.

FIG. 3 shows a structure of a conventional fly cell SRAM cell design configured to stress different devices at the same time under a Time Dependent Dielectric Breakdown bias condition.

FIG. 4A is a structure for testing individual SRAM Bit Cell devices, consistent with an illustrative embodiment.

FIG. 4B is a schematic of the SRAM arrangement of structure in FIG. 4A.

FIG. 5 shows an annotated version of the structure for testing individual SRAM Bit Cell devices of FIG. 4, consistent with an illustrative embodiment.

FIGS. 6A and 6B show a comparison of the conventional 6T_SRAM layout versus the structure for individual SRAM Bit Cell testing 6T_SRAM-RE, consistent with an illustrative embodiment.

FIGS. 7A, 7B and 7C respectively show the modified design of a 6T SRAM, a chart identifying devices to be stressed and their biasing conditions for Time Dependent Dielectric Breakdown stress testing, and an example of Time Dependent Dielectric Breakdown stressing in inversion for an NFET, consistent with an illustrative embodiment.

FIG. 8 is a flowchart illustrating a computer-implemented method of Time Dependent Dielectric Breakdown stressing of an individual bit cell using the biasing conditions shown in FIG. 7, consistent with an illustrative embodiment.

### DETAILED DESCRIPTION

### Introduction

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings. It is to be understood that the present disclosure is not limited to the depictions in the drawings, as there may be fewer elements or more elements than shown and described.

A standard cell library is defined as an adopted cell collection of low-level electronic logic functions of a semiconductor. For example, flip-flops, buffers, latches, AND, OR, INVERT flip-flops, cells may be constructed as fixed-height, full-custom cells having a variable width. Standard cell methodology is a method of designing cells, such as SRAM bit cells according to a specific formula. The illustrative embodiments disclosed herein conform to the adopted library cell design methodologies of SRAM-6T.

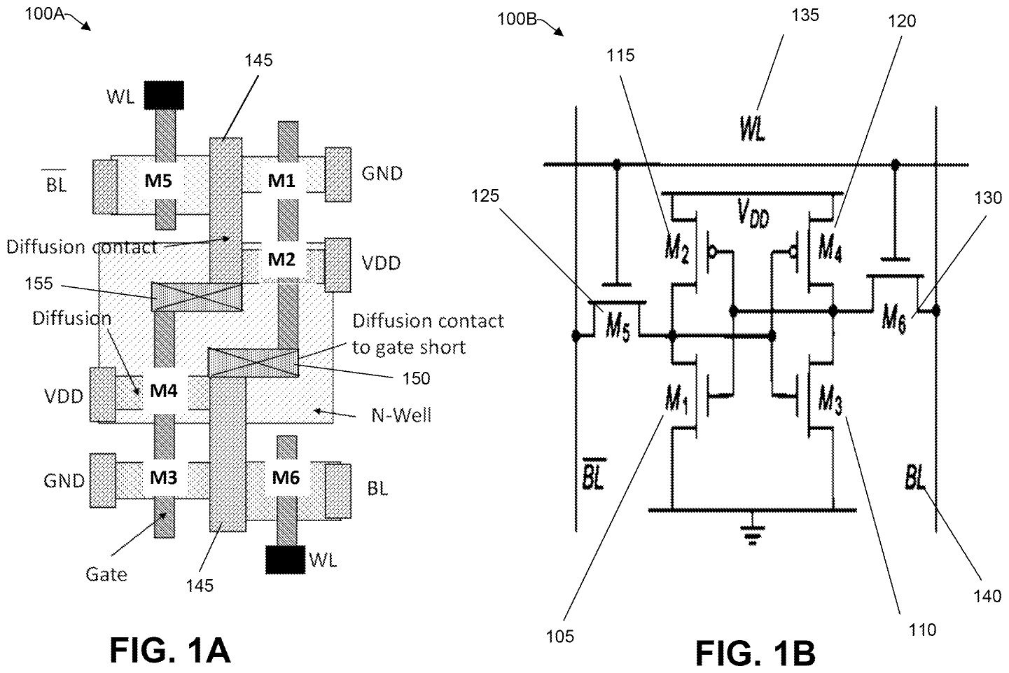

As shown in FIGS. 1A and 1B, a conventional SRAM cell 100A, 100B may comprise six MOSFETS and is typically referred to as a 6T SRAM cell. There are typically four transistors (e.g., M1 105, M2 115, M3 110, and M4 120) in the SRAM cell that store bits. In this example, M1 and M3 are NFETS, and M2 and M4 and PFETS. The four transistors form two cross-coupled inverters. Each of the bits in the cell is stored on the four transistors. The 6T SRAM storage cell has two stable states, which are designated as 0 and 1. There are also typically two additional transistors (M5 125, M6 130) connected to word line 135 and bit line 140 that are configured as pass gates (PG) to control the access to a storage cell during read and write operations. FIG. 1A also shows two diffusion contacts 145 connected to first gate short element 150 and second gate short element 155. The first gate short element 150 and the second gate shorts element 155 connect gates to the drain, but an unintended consequence of this configuration is there cannot be individual reliability testing because the gates of M3 and M4 are connected, and the gates of M1 and M2 are also connected.

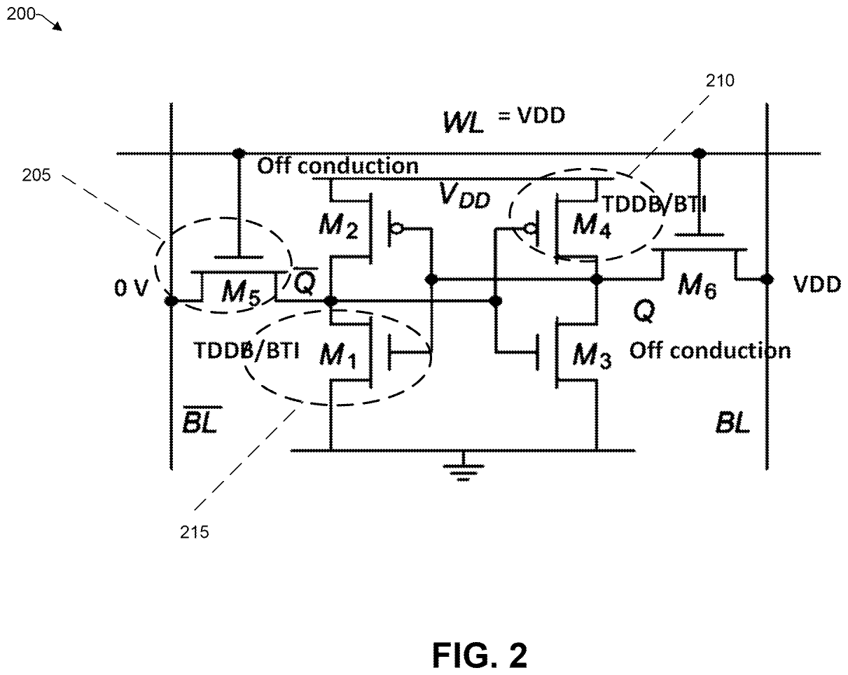

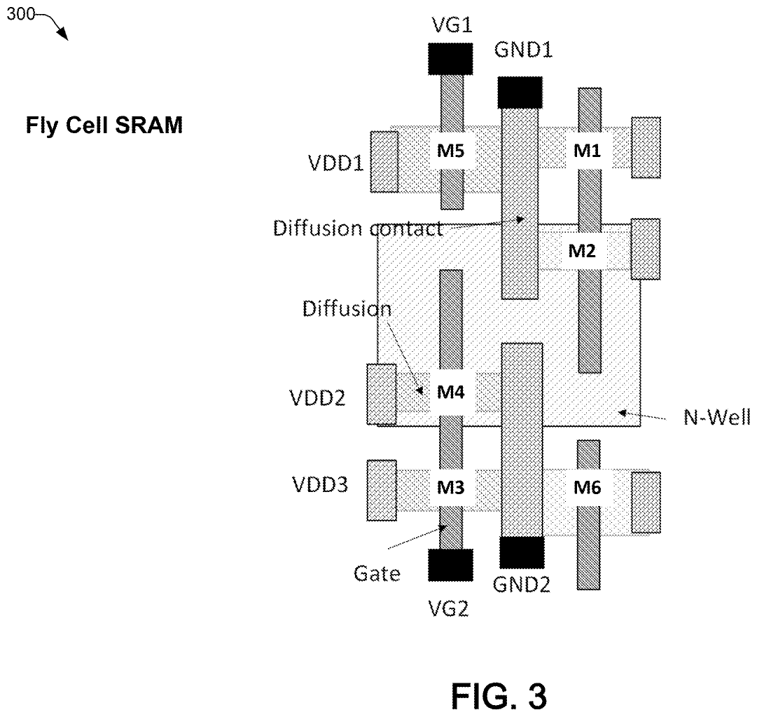

As part of an SRAM technology qualification, an SRAM Bit Cell device (e.g., Pull UP (PU), Pull Down (PD), Pass Gate (PG)) nested in an SRAM environment is stress tested. The intent of stress testing is to verify whether a given Bit Cell device has the same reliability of its logic counterpart. This evaluation permits verifying whether the same Time Dependent Dielectric Breakdown (TDDB) modeling may be applied to both a given SRAM Bit cell device and its logic counterpart to predict an End of Life (EOL) aging. A particular interest is the comparison of the TDDB of a given SRAM device if stressed individually as is typically done for its logic device counterpart. However, there is currently no structure and stress/test method in SRAM that allows for the TDDB stress of an individual given Bit Cell device in the SRAM environment. The reason that no structure and/or stress/test method exists is because of the cross-coupling of the three bit cell devices (PU, PD, PG) due to the wiring of two back-to-back inverters in an SRAM configuration, such as in a 6T SRAM configuration shown in FIG. 1A. Accordingly, TDDB stressing is typically performed in a conventional SRAM 200 such as shown in FIG. 2, or in a Fly Cell SRAM design 300 such as shown in FIG. 3. Neither of the SRAM structures shown in FIG. 2 and FIG. 3 can be used for direct TDDB stressing of an individual Bit Cell device.

With further regard to TDDB stressing in conventional SRAM designs, the key Front End of Line (FEOL) reliability mechanisms contribute simultaneously to aging of the BIT cell device (PG/PU/PD) during SRAM operation of product stressing. For example, with reference to FIG. 2, there are three different bit cell devices M1, M4, and M5 (in dashed circles) that are exposed to TDDB aging at the same time. Devices M2, M3, and M6 are identified as being in an OFF conduction status.

FIG. 3 shows a Fly Cell SRAM design 300 that is configured to stress different bit devices. The structure in FIG. 3 is similar to FIG. 1A but at least one difference is that the diffusion contact to gate short connection is removed. In the Fly Cell SRAM design 300, different devices may be stressed at the same time under a TDDB configuration. In FIG. 3, the device M3 and device M4 are stressed simultaneously. However, the structure shown in FIG. 3 does not permit an individual stressing on the PU device (M4) or PD device (M3) under TDDB conditions ((e.g., VDD2=0V, VDD3=Float) VG2=Vgstress>0). The reason the individual stressing cannot be performed is because device M4 will be in accumulation and device M3 in inversion. Under TDDB conditions a gate dielectric breakdown can take place in either one of device M3 and device M4.

### Overview

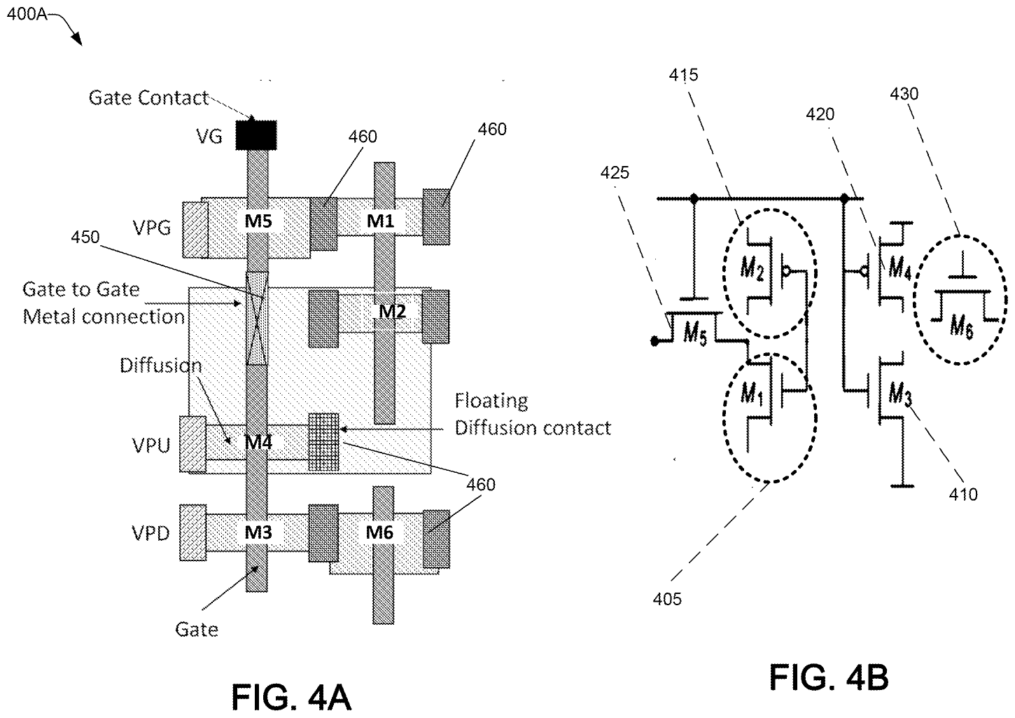

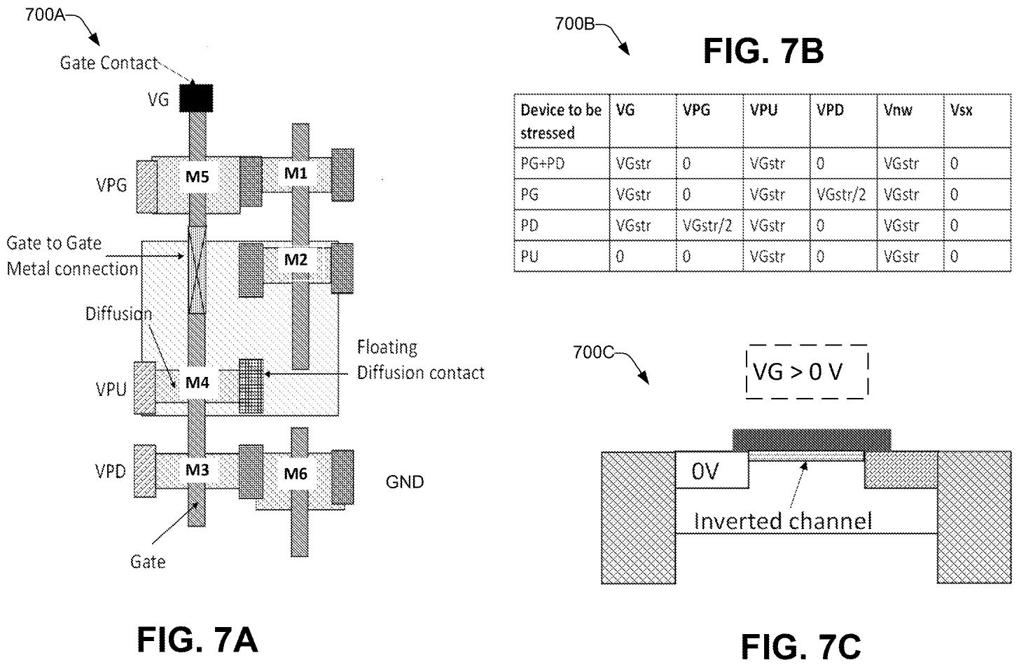

FIG. 4A shows a structure 400A for testing individual SRAM Bit Cell Devices, consistent with an illustrative embodiment. It should be first noted that the unique SRAM rewiring in the device shown in FIG. 4A is in compliance with typical SRAM 6T thin cell of the adopted library cell design methodologies to maintain the Front End of line (FEOL) and SRAM bit cell device environment, yet allow for TDDB stressing on a single SRAM Bit Cell device. The present disclosure teaches that TDDB stressing of individual SRAM Bit Cell Devices may be based on a combination of an SRAM cell structural change in the Back End of the Line (BEOL) wiring in combination with certain TDDB biasing conditions. For example, a gate-to-gate metal connection 450 and floating diffusion contacts permit the individual TDDB stress testing. Voltage contacts for the pull up device M4, the pull down device M3, and pass gate M5 can be individually applied to these bit cell devices for individual stress testing, typically using a TDDB test. FIG. 7B is a table that illustrates the devices that may be stressed individually include pull up, pull down, pass gate, and pass gate and pull down simultaneously.

A new modified design of a six transistor SRAM layout is referred to herein as “SRAM_6T_Rewired” (SRAM_6T_RE). The modified design is created from a conventional SRAM_6T layout. A novel and non-obvious modified wiring design and a modified diffusion contact design provide for the Bit Cell Devices (PU, PD, PG) while conforming to FEOL and an adopted library cell design methodologies of SRAM-6T. However, the SRAM_6T_RE is constructed to permit individual reliability testing of each of the transistors, resulting in TDDB enhanced accuracy and overall reliability based on the enhanced accuracy of the reliability stress testing. In addition, the individual stress testing results in a reduction in wear-out of the SRAM device. For example, there is a reduction in the gate dielectric breakdown that can take place in a conventional 6T SRAM layout when stress/reliability tested. Conventional 6T SRAM layouts are prone to simultaneous aging of the Bit Cell Devices (e.g., PG, PU, PD) during SRAM operation or product testing (e.g., TDDB aging).

In addition to the above-description modification to the wiring, there are novel TDDB bias conditions disclosed to select a given Bit cell device to be stressed for TDDB aging using the SRAM_6T_RE layout.

Additional advantages of the method and device of the present disclosure are disclosed herein.

### Example Structure for Testing Individual SRAM Bit Cell Devices

FIG. 4A is a structure for testing individual SRAM Bit Cell devices, consistent with an illustrative embodiment, and FIG. 4B is a schematic of the SRAM arrangement of structure in FIG. 4A. FIG. 4A is discussed in detail in the Overview. To avoid duplication, it is expressed herein that the gate-to-gate metal connection 450 enables transistors labeled M5, M4, and M3 to have a shared gate connection. This shared gate connection of M5, M4 and M3 is referred to herein as a first gate connection. On the other hand, the first and second transistors M1 and M2 also have a shared gate, which is referred to as a second shared gate connection to distinguish from the first shared gate connection. FIG. 4A also shows the floating diffusion contacts 460 that are used instead of a diffusion contact 145 such as shown in FIG. 1A. The floating diffusion contacts 460 shown in FIG. 4A are shorter than the diffusion contacts 145 to allow for isolation of the M1, M2 and M6, and enable the gate-to-gate metal connection, which may be a metal layer.

FIG. 4B is a schematic of the SRAM arrangement of structure in FIG. 4A. FIG. 4B shows access transistors M5 425 and M6 430, along with M7 420 and M3 410 in what is sometimes referred to as a right-facing inverter, and M1 405 and M2 415 in a left-facing inverter. M1, M2 and M6 are all shown within dashed circles to identify that these transistors are isolated from SRAM bit cell devices of M5, M4 and M3. The diffusion gates, as disclosed herein may be provided for electrically isolating the respective bit cells from the first transistor, the second transistor, and the sixth transistor of the SRAM.

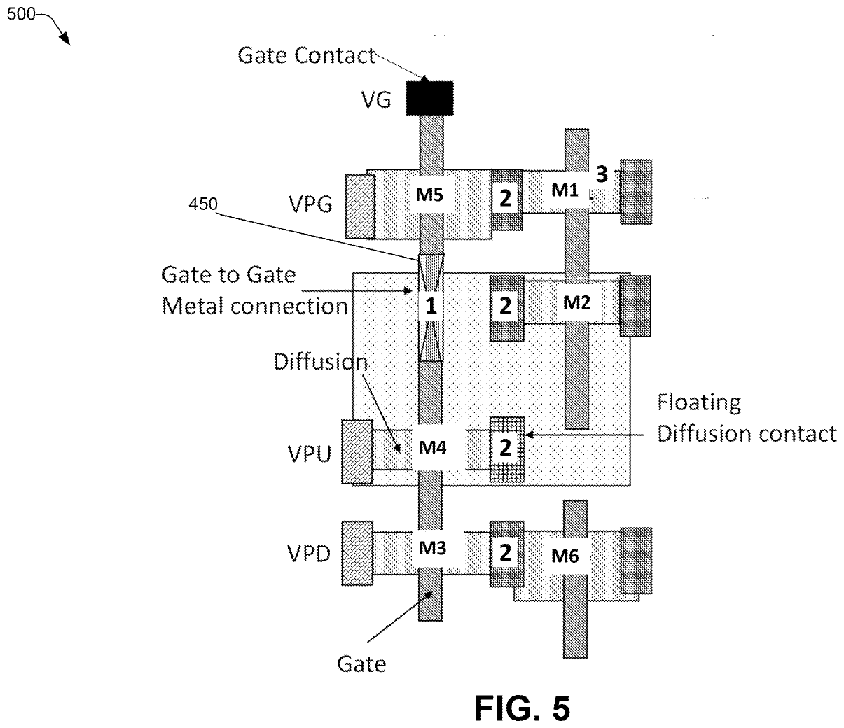

FIG. 5 shows an annotated version of the structure 500 for testing individual SRAM Bit Cell devices of FIG. 4, consistent with an illustrative embodiment. The SRAM rewiring configuration to obtain a modified SRAM_6T_RE disclosed herein also maintains compliance within the typical SRAM 6T thin cell of an adopted library cell design methodologies regarding the FEOL SRAM bit cell FEOL Device Environment.

One non-limiting objective of the proposed SRAM rewiring (SRAM_6T_RE) is to be able to run TDDB stresses in the individual SRAM MOSFET (PU, PD, PG) in the same FEOL environment experienced by these devices in the standard SRAM Bit Cell (SRAM_6T) making sure that minimal BEOL layout changes are applied.

For example, with regard to the annotations (1), (2), and (3) shown in FIG. 5, in Annotation (1) the M5, M4 and M3 are sharing the same gate contact by implementing a Gate-to-Gate connection 450. In Annotation (2) if the “diffusion contact to gate short” (first gate short element 150, second gate short element 155 shown in FIG. 1A) are not disconnected so as to create the floating diffusion contacts 460, then due to cross-talk, the TDDB readings taken on Vg will not be accurate. In Annotation (3), if the M1 MOSFET is deleted from the given SRAM layout to isolate the M5 MOSFET for TDDB stressing, then due to a change in the M5 FET local layout effects (LLE), the devices characteristics and reliability won't be a representative of the actual M5 MOSFET in the SRAM cell. Hence the actual SRAM cell and SRAM_RE cell should have the same FEOL (Font-end-of-the-line) structure to preserve the LLE effect.

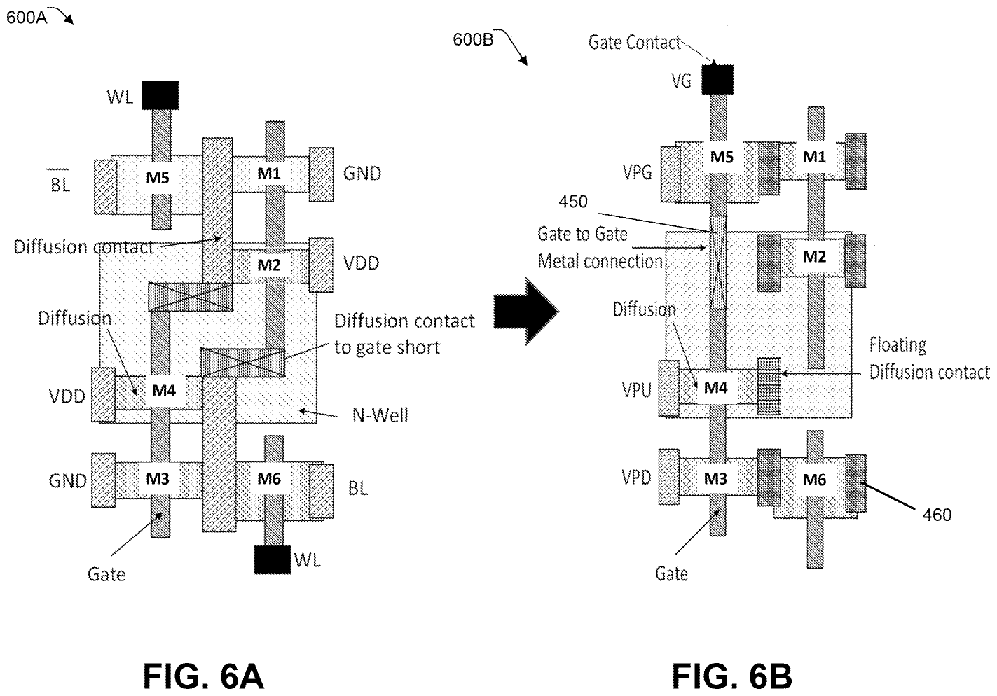

FIGS. 6A and 6B show a comparison of the conventional 6T SRAM layout 600A versus the structure for individual SRAM Bit Cell testing 600B, consistent with an illustrative embodiment. SRAM novel rewiring configuration is only allowed within the typical SRAM 6T thin cell adopted library cell design methodologies. To reiterate, the rewiring of a standard 6T SRAM such as in FIG. 6A to obtain the 6T_SRAM_RE according to the present disclosure enables TDDB stressing in inversion conditions of individual bit cell devices (PG=M5, PU=M4, PD=M3). It is noted that the individual BIT cell device FEOL layout is not modified up to the diffusion contact. The PG and PU+PD inverter gates may be connected by a metal level (not shown).

Referring to FIG. 6B, one diffusion contact 460 of each Bit Cell devices is floating, while the other one is biased (VPG, VPU, VPD). The removal of the inverter gate to diffusion contact metal short 150, 155 shown in FIG. 6A with the, gate-to-gate metal connection 450 rewiring and the floating diffusion contacts 460 shown in FIG. 6B allows for the control of channel inversion of each device independently even if the 3 bit cell devices (PU, PD, PG) are sharing the same gate.

Still referring to FIG. 6B, the TDDB stress testing is performed on the structure for individual SRAM Bit Cell testing 600B by using the same SRAM input pads shown in the device in FIG. 6A (WL, BL, VDD, Gnd, renamed in FIG. 6B as VG, VPG, VPU, VPD). These pads are renamed. Again, it is to be understood that the present disclosure is not limited to any particular stressing method to test for reliability. Other types of tests may also be applied to the rewired SRAM structure shown in FIG. 6B.

FIGS. 7A, 7B, and 7C respectively show the rewired SRAM, a chart identifying devices to be stressed and their biasing conditions for TDDB stress testing, and an example of TDDB stressing in inversion for an NFET, consistent with an illustrative embodiment.

The SRAM Bit Cell device 700A may be TDDB biased to stress individual SRAM Bit Cell Devices.

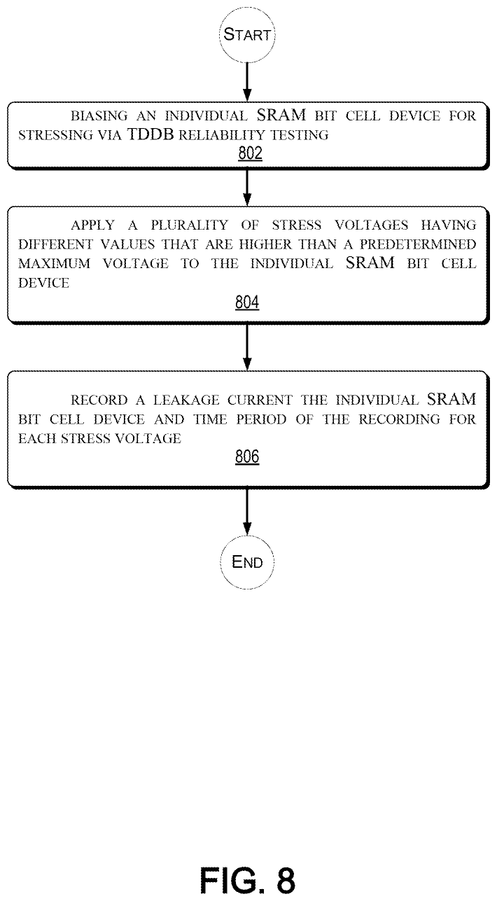

With the foregoing overview of the example architecture, it may be helpful now to consider a high-level discussion of an example process. To that end, FIG. 8 is a flowchart illustrating a computer-implemented method of TDDB stressing of an individual bit cell using the biasing conditions shown in FIG. 7, consistent with an illustrative embodiment. While it is contemplated to TDDB stress test a selected Bit cell device for TDDB aging, the present disclosure is not limited to a particular test.

More particularly, with reference to FIG. 7B, the modified SRAM layout shown in FIG. 7A, various combinations of PG, PU and PD bit cell devices may be stressed tested for the TDDB inversion according to the table in FIG. 7B. Without the various combination of bias conditions, there would be great difficulty (even if possible) to run a TDDB stress test on the (SRAM_6T_RE) cell. The device to be stressed can be selected from the table, including PG plus PD, PG, PD, PU. The pad on the gate contact VG receives a voltage (VGstress). Other voltage values are shown in the table including Vnw and Vsx. Vnw refers to an N-WELL PU biasing voltage and Vsx is a Substrate (P-WELL) biasing voltage. In this design a PU N-Well and PG/PD substrate (P-Well) are connected separately to a pad by an appropriate BEOL wiring. The different bias combinations (VG, VPG, VPU, VPD, Vnw, Vsx) are selected to stress a given device combination (PG, PD, PU, PG+PD) in inversion.

FIG. 7C shows an example of TDDB stress testing in inversion for an NFET. The value of VG>0V, and the channel inversion is guaranteed even with one contact diffusion floating. FIG. 7C illustrates that TDDB stressing will be sufficient even with one diffusion floating as long as the stress is in an inversion mode. This attribute justifies the effectiveness of TDDB stressing of M4 even with floating diffusions.

### Example Process

FIG. 8 is shown as a collection of blocks, in a logical order, which represents a sequence of operations that can be implemented in hardware, software, or a combination thereof. In the context of software, the blocks represent computer-executable instructions that, when executed by one or more processors, perform the recited operations. Generally, computer-executable instructions may include routines, programs, objects, components, data structures, and the like that perform functions or implement abstract data types. In each process, the order in which the operations are described is not intended to be construed as a limitation, and any number of the described blocks can be combined in any order and/or performed in parallel to implement the process. In the embodiment illustrated by FIG. 8, it is contemplated that the SRAM bit cell device has been “rewire”, e.g., built according to one of the embodiments of a 6T SRAM RE structure such as shown in FIGS. 4A and 4B, or similar structure. It is to be understood that the method is also applicable to 8T, 10T or whatever quantity of transistors (XT) that may be used as a bit cell device, if their structure is similar to the 6T structure shown herein for individual testing. In one particular embodiment, the plurality of transistors includes six MOS transistors, in which three transistors are PFET and three transistors are NFET, but the present disclosure is not limited to this structure.

At operation 802, an individual SRAM bit cell that has been selected for reliability testing is biased for operation. A computer may select each of the individual bit cell devices in succession or an order of bit cell devices to be tested, and control a performance of a reliability test, such as a TDDB stressing. Multiple iterations may be performed.

At operation 804, the stress testing may include applying to the individual SRAM bit cell device multiple combinations of stress voltages having different values higher than a predetermined maximum use voltage to a given SRAM bit cell device.

At operation 806, a leakage current is recorded for each applied voltage to determine a dielectric breakdown. The time is also recorded so that a time period before breakdown occurs is recorded for each applied stress voltage. The computer-executable method may include graphically plotting the values for future use of the particular bit cell under test. The method may be repeated for a predetermined number of iterations, and then ends after the last time operation 806 is performed. The data may be stored or transmitted and the plotting may occur elsewhere by another entity.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. For example, although the illustrative embodiments show 6T SRAM configurations, the present disclosure is applicable to configurations with more than six transistors. For example, the teachings of the present disclosure may be applied to 8T SRAM, 10T SRAM, or any other XT SRAM cell. The reliability testing is not limited to TDDB.

The flowchart, and diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device configured for individual reliability testing of a bit cell device in a static random-access memory (SRAM), the semiconductor device comprising:
a static random-access memory (SRAM) including a plurality of transistors;
a first inverter;
a second inverter cross-coupled to the first inverter; and
a first access transistor and a second access transistor of the plurality of transistors are configured to share a word line bias; wherein:
the second inverter and the second access transistor have a shared first gate connection and form respective bit cell devices, each with two contacts;
at least one contact of each of the respective bit cell devices comprises a floating diffusion contact; and
a second contact of each of the respective bit cell devices is configured to be individually biased for reliability testing.

2. The semiconductor device of claim 1, wherein:
the first inverter comprises a first transistor and a second transistor of the plurality of transistors;
the second inverter comprises a third transistor and a fourth transistor of the plurality of transistors; and
the first access transistor and the second access transistor respectively comprise a fifth transistor and a sixth transistor of the SRAM,
wherein the third transistor, fourth transistor and fifth transistor have the shared first gate connection.

3. The semiconductor device of claim 2, wherein a gate of the first transistor and a gate of the second transistor are connected to form a shared second gate connection.

4. The semiconductor device of claim 2, wherein the shared first gate connection includes a gate of the fifth transistor, a gate of the third transistor and a gate of the fourth transistor, wherein the gate of the fifth transistor is connected via an inline gate-to-gate metal connection.

5. The semiconductor device of claim 2, wherein the first transistor, the second transistor and the sixth transistor are electrically isolated from the third transistor, fourth transistor, and fifth transistor.

6. The semiconductor device of claim 2, wherein the SRAM comprises a modified design 6-transistor SRAM (SRAM_6T_RE) without diffusion-contact-to-inverter gate-short connections, and further comprises a gate-to-gate metal connection that connects a gate of the fifth transistor to a shared gate of the third transistor and the fourth transistor to form the shared first gate connection.

7. The semiconductor device of claim 6, wherein the modified design SRAM_6T_RE is further configured for a Time Dependent Dielectric Breakdown of the respective bit cell devices by including floating diffusion contacts to isolate the first transistor, the second transistor and the sixth transistor.

8. The semiconductor device of claim 6, further comprising a plurality of SRAM memory devices and at least one modified SRAM_6T_RE configured for TDDB reliability testing.

9. The semiconductor device of claim 6, wherein the modified design SRAM_6T_RE is configured to retain each of the respective bit cell devices comprising a pull-up (PU), a pull-down (PD) and pass gate (PG) devices while conforming to a Front End of Line (FEOL) adopted library cell design methodologies of an SRAM-6T.

10. The semiconductor device of claim 9, wherein a given number of single bit cells devices of the modified design 6T_SRAM_RE are wired in parallel to yield an assigned total area for a given bit cell device type.

11. A computer-implemented method of biasing a static random-access memory (SRAM) bit cell device of an SRAM memory modified for individual bit cell Time Dependent Dielectric Breakdown (TDDB) stress reliability testing, the method comprising:
biasing an individual SRAM bit cell device via TDDB reliability testing;
applying a plurality of stress voltages having different values that are higher than a predetermined maximum use voltage to the individual SRAM bit cell device; and
recording a leakage current of the individual SRAM bit cell device undergoing the TDDB reliability testing and a time period of the recording,
wherein the individual SRAM bit cell device comprises a pull up gate, a pull down gate, a pass gate, or a combination of a pass gate and a pull down gate.

12. The computer-implemented method of claim 11, wherein the SRAM bit cell device is configured to include a gate-to-gate-metal connection and floating diffusion contacts on at least one contact of each bit cell, and the method further comprising applying the plurality of stress voltages in increasing increments and recording the leakage current that occurred over a predetermined time period.

13. A method of forming a semiconductor for individual reliability testing of a bit cell device in a static random-access memory (SRAM), the method comprising:
providing a static random-access memory (SRAM) including a plurality of transistors;
forming a first inverter and a second inverter cross-coupled to the first inverter from at least some of the plurality of transistors;
providing a first access transistor and a second access transistor of the plurality of transistors configured to share a word line bias;
connecting the second inverter and the second access transistor to have a shared first gate connection and to form respective bit cell devices each with two contacts; and
configuring a second contact of each of the respective bit cell devices to be individually biased for reliability testing,
wherein at least one contact of each of the respective bit cell devices comprises a floating diffusion contact.

14. The method according to claim 13, wherein:
the first inverter is formed by connecting a first transistor to a second transistor of the plurality of transistors;
the second inverter is formed by connecting a third transistor to a fourth transistor of the plurality of transistors; and
the first access transistor and the second access transistor are formed of a fifth transistor and a sixth transistor of the SRAM; and the method further comprising:
providing the shared first gate connection by connecting a gate of the fifth transistor to a gate of the third transistor and a gate of the fourth transistor.

15. The method according to claim 14, providing a gate-to-gate metal connection to connect the gate of the fifth transistor to the gate of the third transistor and the gate of the fourth transistor.

16. The method according to claim 15, further comprising electrically isolating the respective bit cells from the first transistor, the second transistor, and the sixth transistor of the SRAM.

17. The method according to claim 15, wherein the forming of the first inverter includes connecting a PFET to an NFET, and forming the second inverter includes forming another PFET to another NFET.

18. The method according to claim 17, further comprising providing the SRAM with floating diffusion contacts to isolate the first transistor, the second transistor and the sixth transistor for Time Dependent Dielectric Breakdown of the respective bit cell devices.

19. The method according to claim 17, further comprising providing a plurality of static ram memory devices and at least one SRAM for TDDB reliability testing.

20. The method according to claim 17, further comprising retaining by the SRAM each of the respective bit cell devices by providing a pull-up (PU), pull-down (PD) and pass gate (PG) circuitry that conforms to Front End of Line (FEOL) and adopted library cell design methodologies of an SRAM-6T.
